(19) United States
(12) Patent Application Publication
(10) Pub. No.: US 2022/0402146 A1
(43) Pub. Date: Dec. 22, 2022

(54) TESTING SYSTEM AND METHOD OF TESTING AND TRANSFERRING LIGHT-EMITTING ELEMENT

(71) Applicant: WIN SEMICONDUCTORS CORP., Taoyuan City (TW)

(72) Inventor: Shu-Jeng YEH, TAOYUAN CITY (TW)

(21) Appl. No.: 17/709,758

(22) Filed: Mar. 31, 2022

Related U.S. Application Data
(60) Provisional application No. 63/212,174, filed on Jun. 18, 2021.

(51) Int. Cl. B25J 15/06; B65G 47/91

(52) U.S. Cl. CPC B25J 15/0616; B65G 47/91

(57) ABSTRACT

A method of transferring a light-emitting element in a testing system includes transferring the light-emitting element to a predetermined position by a transferring component, and vacuuming the at least one vacuum hole to attract the light-emitting element. The predetermined position is spaced apart a distance from at least one vacuum hole, and the distance is greater than half of a width of the light-emitting element.

### CROSS REFERENCE TO RELATED APPLICATIONS

This application claims priority of provisional application of U.S. patent application Ser. No. 63/212,174 filed on Jun. 18, 2021, the entirety of which is incorporated by reference herein.

### BACKGROUND

### Technical Field

The present disclosure relates to a testing system, and in particular it relates to transferring and testing light-emitting elements within a testing system.

### Description of the Related Art

Light-emitting elements are commonly used as light sources in applications involving optical communications. Such elements can generate light in response to the application of an electrical signal.

The light-emitting element may be tested before being packaged. This testing incurs additional costs and longer cycle times, while the complexity of testing chip-level elements may compromise the accuracy of the test results. Therefore, these and related issues need to be addressed through the design and optimization of the testing system.

### SUMMARY

In an embodiment, a method of transferring a light-emitting element includes transferring the light-emitting element to a predetermined position by a transferring component, and vacuuming the at least one vacuum hole to attract the light-emitting element. The predetermined position is spaced apart a distance from at least one vacuum hole, and the distance is greater than half of a width of the light-emitting element.

In another embodiment, a testing system for testing a light-emitting element having a light-emitting surface includes at least one probe for probing the light-emitting element in a probing direction perpendicular to a normal direction of the light-emitting surface in a top view.

In yet other embodiment, a method of testing a light-emitting element having a light-emitting surface includes positioning the light-emitting element on a supporting stage, probing the light-emitting element with at least one probe, and sensing a light emitted from the light-emitting surface. A probing direction of the at least one probe is substantially perpendicular to a normal direction of the light-emitting surface in a top view.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a 3D view of a light-emitting element, according to some embodiments of the present disclosure.

FIG. 2 is a top view of a testing system, according to some embodiments of the present disclosure.

FIGS. 3 and 4 are respectively a top view and a cross-sectional view of a testing system, according to other embodiments of the present disclosure.

FIG. 5 is a flow diagram of an exemplary method for transferring the light-emitting element, according to other embodiments of the present disclosure.

FIGS. 6, 7, and 8 are top views of testing systems with various designs, according to other embodiments of the present disclosure.

FIG. 9 is a flow diagram of an exemplary method for testing the light-emitting element, according to some embodiments of the present disclosure.

FIG. 10 is a top view of a testing system, according to yet other embodiments of the present disclosure.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on or disposed on a second feature in the description that follows may include embodiments in which the first feature and second feature are formed or disposed in direct contact, and may also include embodiments in which additional features may be formed or disposed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” may mean ±20%, ±10%, ±5%, ±3%, ±2%, ±1%, or ±0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

In response to the increasing demand for higher testing quality, the testing system and method for testing semiconductor devices have become a critical concern. In particular, performing testing on the chip-level device poses more challenges than wafer-level device, due to the significant dimensional difference.

According to some embodiments of the present disclosure, the light-emitting element may be fixed at a supporting stage (such as a chuck) of the testing system, with the side surface emitting light (also known as an output facet) facing toward an optical sensor for sensing the emitted light. After that, one or more probes may be introduced to contact the top surface of the light-emitting element. The probes may function as anode contacts that supply the necessary bias voltage. The bottom surface of the light-emitting element may be electrically coupled to a cathode contact through the chuck for electrical ground, but the present disclosure is not limited thereto.

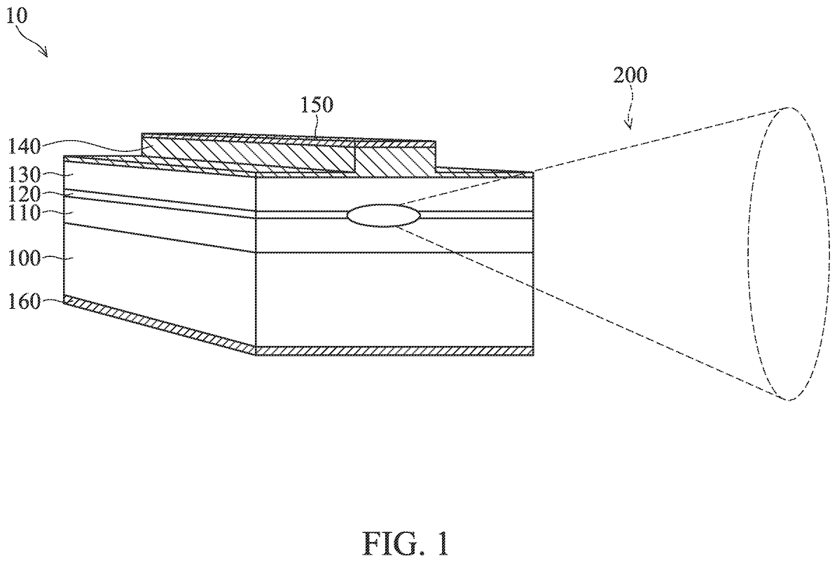

FIG. 1 is a 3D view of a light-emitting element 10, according to some embodiments of the present disclosure. In some embodiments, the light-emitting element 10 may be a light-emitting diode (LED), an edge-emitting laser (EEL) diode, a vertical cavity surface emitting laser (VCSEL) diode, or any suitable light-emitting element, but the present disclosure is not limited thereto. According to some embodiments of the present disclosure, the light-emitting element 10 may include a substrate 100, a first semiconductor layer 110, an active layer 120, a second semiconductor layer 130, a contact metal layer 140, a top electrode 150, and a bottom electrode 160. Take the edge-emitting laser for example, a light beam 200 may be emitted from one of the side surfaces of the light-emitting element 10. As previously mentioned, the side surface where the light beam 200 emitted from is the output facet of the light-emitting element 10, which will be denoted as an output facet 10S in subsequent figures.

In some embodiments, the substrate 100 may also be, for example, a wafer or a chip, but the present disclosure is not limited thereto. In some embodiments, the substrate 100 may be a semiconductor substrate, a ceramic substrate, a glass substrate, or any suitable substrate, but the present disclosure is not limited thereto. Furthermore, in some embodiments, the materials of the semiconductor substrate may include an elemental semiconductor (such as silicon and/or germanium), a compound semiconductor (such as gallium nitride (GaN), silicon carbide (SiC), gallium arsenide (GaAs), gallium phosphide (GaP), indium phosphide (InP), indium arsenide (InAs), and/or indium antimonide (InSb)), an alloy semiconductor (such as silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenide phosphide (GaInAsP) alloy), or a combination thereof, but the present disclosure is not limited thereto. In some embodiments, the substrate 100 may be a photoelectric conversion substrate, such as a silicon substrate or an organic photoelectric conversion layer.

In other embodiments, the substrate 100 may include a semiconductor on insulator (SOI) substrate. The semiconductor on insulator substrate may include a base plate, an insulating layer (e.g. a buried oxide layer) disposed on the base plate, and a semiconductor layer disposed on the buried oxide layer. Furthermore, the substrate 100 may be an n-type or a p-type conductive type.

In some embodiments, the substrate 100 may be a backplane for multiple light-emitting elements (e.g. edge-emitting laser chips). The backplane may further include additional elements (not shown for simplicity), such as thin film transistors (TFT), complementary metal-oxide semiconductors (CMOS), printed circuit boards (PCB), driving components, suitable conductive features, the like, or combinations thereof. Conductive features may include, but not limited to, cobalt (Co), ruthenium (Ru), aluminum (Al), tungsten (W), copper (Cu), titanium (Ti), tantalum (Ta), silver (Ag), gold (Au), platinum (Pt), nickel (Ni), zinc (Zn), chromium (Cr), molybdenum (Mo), niobium (Nb), the like, combinations thereof, or the multiple layers thereof. These elements provide circuitry that connects to the light-emitting elements. In other embodiments, the substrate 100 may include an epitaxial structure that functions as an optical waveguide. Under current or voltage appliance, the epitaxial structure may display oscillating bandgap characteristics that results in higher energy for generating the light beam 200 with higher intensity.

Referring to FIG. 1, the first semiconductor layer 110, the active layer 120, and the second semiconductor layer 130 may be sequentially disposed on the substrate 100. The active layer 120 may be disposed between the first semiconductor layer 110 and the second semiconductor layer 130. In other words, first semiconductor layer 110 and the second semiconductor layer 130 may serve as a cladding configuration for the active layer 120. The light beam 200 of the light-emitting element 10 may be emitted from the active layer 120. In some embodiments, the active layer 120 may emit blue light, red light, green light, white light, cyan light, magenta light, yellow light, the like, or combinations thereof.

Materials of the first semiconductor layer 110 and the second semiconductor layer 130 may be selected from II-VI group (for example, zinc selenide (ZnSe)) or III-V group (for example, gallium nitride (GaN), aluminum nitride (AlN), indium nitride (InN), indium gallium nitride (InGaN), aluminum gallium nitride (AlGaN), or aluminum indium gallium nitride (AlInGaN)). In some embodiments, one of the first semiconductor layer 110 and the second semiconductor layer 130 may be n-type and the other one may be p-type. For example, the first semiconductor layer 110 may be doped with n-type dopants, such as phosphorus, arsenic, or combinations thereof. The second semiconductor layer 130 may be doped with p-type dopants, such as boron, indium, gallium, or combinations thereof.

The active layer 120 may include at least one undoped semiconductor layer or at least one lightly doped layer. For example, the active layer 120 may be a quantum well (QW), which may include indium gallium nitride (InₓGa₁₋ₓN) or gallium nitride (GaN), but the present disclosure is not limited thereto. In some embodiments, the active layer 120 may be a multiple quantum well (MQW) layer.

Still referring to FIG. 1, the contact metal layer 140 may be disposed on the second semiconductor layer 130. In some embodiments, the contact metal layer 140 is of metal materials that forms an ohmic contact with the underlying semiconductor materials. Materials of the contact metal layer 140 may include opaque metals (such as tungsten (W), aluminum (Al)), opaque metal nitride (such as titanium nitride (TiN)), opaque metal oxide (such as titanium oxide (TiO)), other suitable materials, or combinations thereof, but the present disclosure is not limited thereto.

Referring to FIG. 1, the top electrode 150 may be disposed on the contact metal layer 140. According to some embodiments of the present disclosure, the top electrode 150 may be used for probe contact. As mentioned previously, the probes may function as anode contacts that supply the necessary bias or current. Therefore, the top electrode 150 may also be known as the anode electrode. As shown in FIG. 1, the bottom electrode 160 may be disposed on a backside of the substrate 100, or the surface opposite from the first semiconductor layer 110.

In some embodiments, the active layer 120 of the light-emitting element 10 may include multiple transmission lines that are specifically configured in a single-axial direction, so the light may not emerge from the side surfaces of perpendicular-axial direction (such as the right side surface or the left side surface). Moreover, the light emission side surface (or the output facet) is coated with antireflection (AR) film, while the side surface opposite from the output facet (such as the back side surface) is coated with high reflection (HR) film. Such arrangement may force the emitted light rays reaching the back side surface to be reflected, and the emitted light rays reaching the output facet to be transmitted, thereby ensuring that nearly all the light rays may be emerged from the output facet only. Furthermore, the antireflection film is coated in such way that allows only a certain region of the output facet for light to emit resulting in a more concentrated light beam 200.

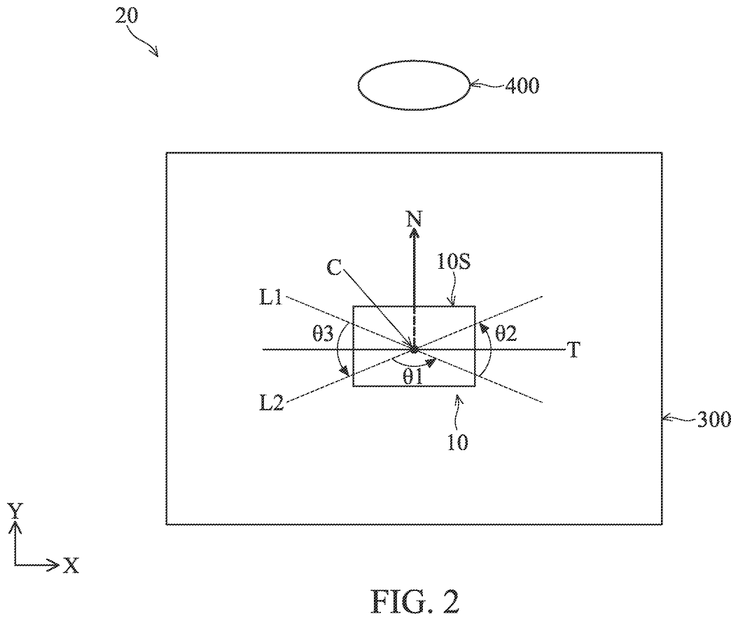

FIG. 2 is a top view of a testing system 20, according to some embodiments of the present disclosure. The testing system 20 illustrates how the probing method may be implemented. The testing system 20 may include a supporting stage 300 and an optical sensor 400, and may be used for testing the light-emitting element 10. The light-emitting element 10 is illustrated from a top view, having an output facet 10S facing the optical sensor 400. A normal direction N of the output facet 10S may be illustrated along the y-axis, and may be directed toward the optical sensor 400. A tangent line T may be substantially illustrated along the x-axis, and may be substantially perpendicular to the normal direction N. Imaginary lines L1 and/or L2 and the tangent line T may intersect at a center point C of the light-emitting element 10. The imaginary lines L1 and L2 may be used to indicate the probing direction of the probe(s) in the top view. In other embodiments, the imaginary lines L1 and L2 may not overlap with the center point C since the top electrode 150 may not cover the center point C. In this case, the imaginary lines L1 and/or L2 and the tangent line T may intersect at a different point where the probe contacts the top electrode 150. For illustrative purpose, the components that clamp the light-emitting element 10 are omitted.

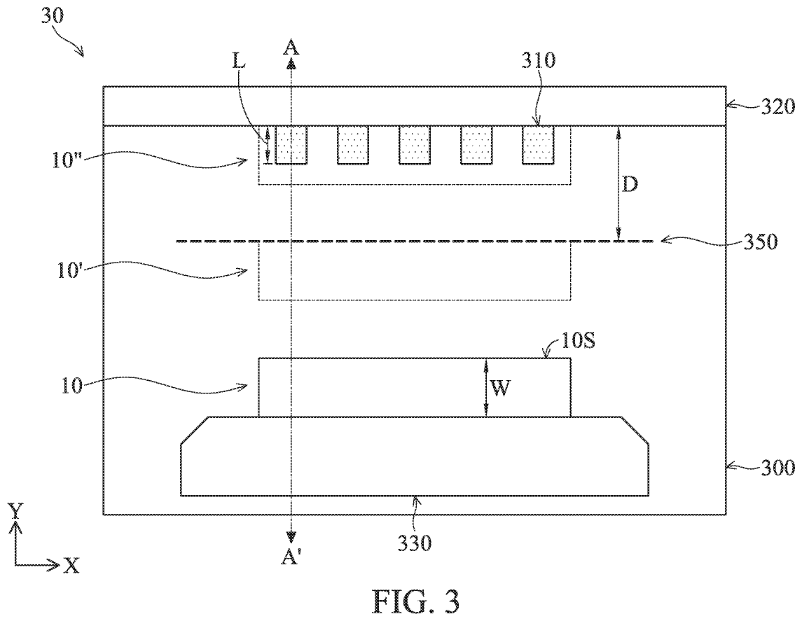

Referring to FIG. 2, the supporting stage 300 may be provided in the testing system 20. The supporting stage 300 may carry the object to be tested, such as the light-emitting element 10. According to some embodiments of the present disclosure, the supporting stage 300 may be a chuck with one or more vacuum holes (shown in FIG. 3) that provide vacuum suction to the light-emitting element 10. If necessary, the supporting stage 300 may be heated or cooled to provide temperature control to the light-emitting element 10. In other embodiments, the supporting stage 300 may be an electrostatic chuck that provides electrostatic charges to attach the light-emitting element 10.

Still referring to FIG. 2, the optical sensor 400 in the testing system 20 may be positioned outside the supporting stage 300. When the light beam 200 is emitted from the output facet 10S of the light-emitting element 10, the optical sensor 400 may receive the optical energy of the light beam 200. According to some embodiments of the present disclosure, the optical sensor 400 may convert the received optical signal(s) into electric signal(s), which in turn may detect the optical performance of the light-emitting element 10. Therefore, if the output facet 10S of the light-emitting element 10 could not be properly aligned with the optical sensor, the optical performance of the light-emitting element 10 may be inaccurately determined by the optical sensor 400.

Referring to FIG. 2, the intersection of the imaginary lines L1 and L2 at the center point C of the light-emitting element 10 may generate a first angle θ1, a second angle θ2, and a third angle θ3.

Conventionally, the probe may approach the light-emitting element 10 from the region defined by the first angle θ1 in the top view, or in the y-axis direction substantially parallel with the normal direction N of the output facet 10S. However, the mechanical force exerted by the probe may inadvertently rotate the light-emitting element 10 away from its original orientation. As mentioned previously, the probe may also tip the light-emitting element 10, causing the light-emitting element 10 to climb onto one of the clamping components with relatively lower thickness. Both situations may cause a severe misalignment between the output facet 10S of the light-emitting element 10 and the optical sensor 400.

According to some embodiments of the present disclosure, from the top view, the probe may be brought in to the light-emitting element 10 from the region defined by the second angle θ2 or the third angle θ3, or in the x-axis direction along the tangent line T. The tangent line T may be considered as the center line of the regions defined by the second angle θ2 and the third angle θ3, but the present disclosure is not limited thereto. Since the tangent line T is substantially perpendicular to the normal direction N of the output facet 10S, the probe's entry direction may also be substantially perpendicular to the normal direction N of the output facet 10S. Should the testing condition requires more than one probes, multiple probes may approach the light-emitting element 10 from both regions defined by the second angle θ2 and the third angle θ3.

When the probe direction does not precisely follow the tangent line T, the region defined by the second angle θ2 or the third angle θ3 may be considered as an acceptable range for the probe's entry direction. According to some embodiments of the present disclosure, the intersecting angle between the imaginary line L1 and the tangent line T, or the intersecting angle between the imaginary line L2 and the tangent line T may be known as an included angle. The included angle may be approximately less than 5° (such as 1°, 2°, 3°, or 4°), but the present disclosure is not limited thereto. In other words, the second angle θ2 or the third angle θ3 should be equivalent to twice the included angle, which may be approximately less than 10° (such as 2°, 4°, 6°, or 8°). The second angle θ2 or the third angle θ3 is the probe's entry window according to the present disclosure.

It should be understood that, the second angle θ2 is supplementary with the first angle θ1, while the third angle θ3 is also supplementary with the first angle θ1. According to the principles of geometry, the sum of the first angle θ1 and the second angle θ2 is 180°, and the sum of the first angle θ1 and the third angle θ3 is also 180°. In other words, the first angle θ1 is much greater than the second angle θ2 or the third angle θ3. Conventionally, when the probe's entry direction is within the much broader region defined by the first angle θ1, the probability of causing misalignment between the output facet 10S and the optical sensor 400 may thus increase.

By limiting the second angle θ2 or the third angle θ3 within 10°, the probe's entry direction may be as close to the tangent line T as possible in a top view. Since the tangent line T may be parallel with the clamping component's extending direction (e.g. the stopper 320 shown in FIG. 3), probing the light-emitting element 10 along the tangent line T can reduce the occurrence that the light-emitting element 10 climbs onto the stopper.

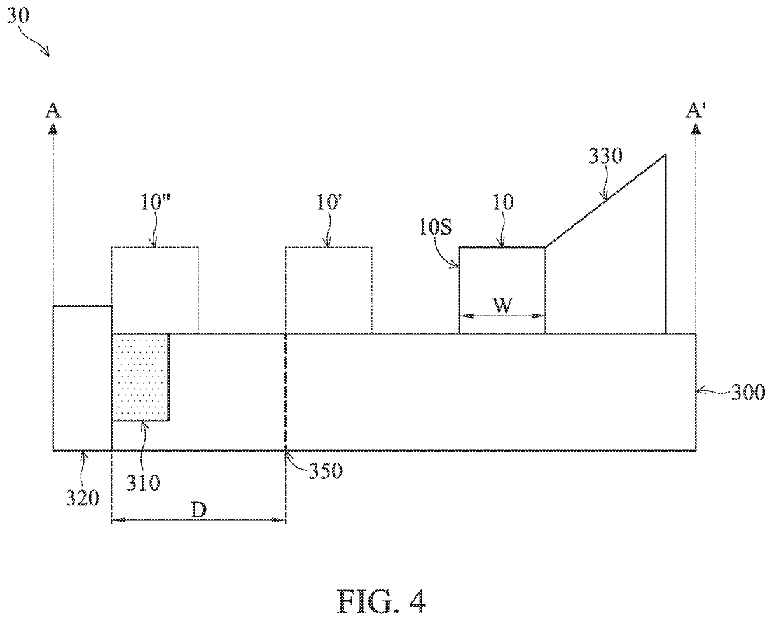

FIGS. 3 and 4 are respectively a top view and a cross-sectional view of a testing system 30, according to other embodiments of the present disclosure. The testing system 30 may be a comprehensive illustration of the testing system 20. According to some embodiments of the present disclosure, the testing system 30 illustrates how the transferring method may be implemented. The testing system 30 may include the supporting stage 300, vacuum holes 310, a stopper 320, and a pusher 330. For illustrative purpose, the normal direction N, the tangent line T, the imaginary lines L1 and/or L2, the center point C, the first angle θ1, the second angle θ2, the third angle θ3, and the optical sensor 400 are omitted.

In some embodiments, the light-emitting element 10 may be a single chip or a bar having multiple chips arranged (undiced) along the x-axis direction. The single chip may include bare die or packaged die. The light-emitting element 10 is illustrated from a top view, with a width W measured along the y-axis direction and the output facet 10S directed toward the stopper 320. When the light-emitting element 10 is the bar with multiple chips, the chips may be arranged to have the output facet 10S of every chip facing the stopper 320, but the present disclosure is not limited thereto. The light-emitting element 10 may be placed at its initial position. As the transferring method is conducting, the light-emitting element 10 may be transferred to an intermediate position 10′, followed by a terminal position 10″ (both denoted by dotted lines). The intermediate position 10′ is defined by a critical line 350 (also known as a predetermined position for the transferring method). The terminal position 10″ is where the light-emitting element 10 is fixed by the vacuum holes 310 and the stopper 320.

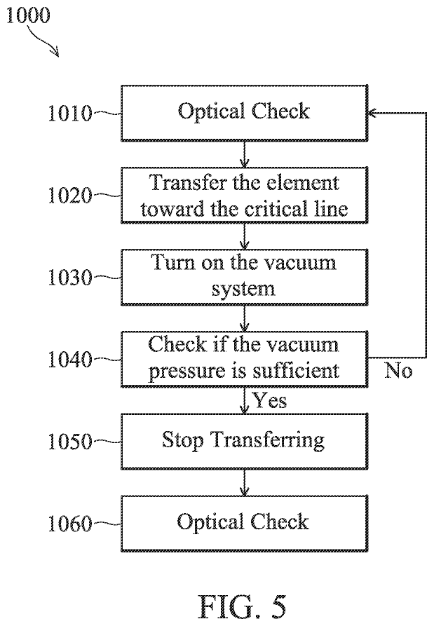

FIG. 5 is a flow diagram of an exemplary method 1000 for transferring the light-emitting element, according to other embodiments of the present disclosure. In subsequent paragraphs, the operations illustrated in FIG. 5 will be described with reference to the top view and the cross-sectional view illustrated in FIG. 3 and FIG. 4, respectively. It should be noted that additional operations may be provided before, during, and after the method 1000, and that some other operations may only be briefly described herein.

As shown in FIG. 5, in an operation 1010 of the method 1000, an optical check is performed. Before performing the optical check, the light-emitting element 10 may be loaded from an input area and placed onto the supporting stage 300 of the testing system 30. A suction nozzle with a mouthpiece of appropriate dimension may be used to attach and to bring the light-emitting element 10 into the testing system 30. The optical check may visually inspect the testing system 30 when the light-emitting element 10 is at its initial position (for example, prior to the transferring method begins), as shown in FIGS. 3 and 4. In some embodiments, the optical check may involve a camera above the supporting stage 300 to check the position or the alignment of the light-emitting element 10 in the top view. The image captured by the camera may be inspected manually and/or using a computer program, but the present disclosure is not limited thereto.

As shown in FIG. 5, in an operation 1020 of the method 1000, transferring the light-emitting element 10 may begin. The pusher 330 may move the light-emitting element 10 toward the critical line 350. The light-emitting element 10 may stop at a position between the initial position and the intermediate position 10′ near the critical line 350. According to some embodiments of the present disclosure, a distance D between the critical line 350 and the stopper 320 may be greater than or equal to half the width W of the light-emitting element 10. In the present embodiment, the distance D is substantially equivalent to twice the width W of the light-emitting element 10, as shown in FIGS. 3 and 4.

As shown in FIG. 5, in an operation 1030 of the method 1000, a vacuum system connecting the vacuum holes 310 may be turned on. For simplicity, the vacuum system and the necessary pipelines connecting to the vacuum holes 310 are not shown. In some embodiments, the supporting stage 300 may be designed to have several recesses at an edge. The stopper 320 may be attached onto the edge to define the vacuum holes 310. As mentioned previously, the stopper 320 may maintain the relatively lower thickness in order to reduce the occurrence that the light beam 200 is inadvertently blocked. The thickness of a portion of the stopper 320 protruding above the surface of the supporting stage 300 is less than half the thickness of the light-emitting element 10. The thickness may refer to the maximum thickness of the portion of the stopper 320. When the vacuum system is turned on, the vacuum holes 310 may have the ability of vacuum suction.

As shown in FIG. 5, in an operation 1040 of the method 1000, the vacuum pressure is checked by a pressure sensor in the vacuum system (not shown for simplicity). Under an ideal situation, when the vacuum system is turned on, the vacuum holes 310 may attract the light-emitting element 10 adjacent to the critical line 350, according to the principles of aerodynamics. Once the vacuum holes 130 are covered by the light-emitting element 10 at the terminal position 10″, the vacuum suction may be in effect. When the light-emitting element 10 is properly being suctioned, the vacuum pressure should reach a sufficient value which may be predetermined before transferring. That is, the vacuum pressure should be greater than or equal to a predetermined value.

In some embodiments, the dimension of one of the vacuum holes may be less than the testing object to be suctioned. Therefore, the dimension (e.g. a length L) of one of the vacuum holes 310 is less than the width W of the light-emitting element 10, such as less than 0.5 of the width W or 0.8 of the width W, but the present disclosure is not limited thereto. In order to have an effective vacuum suction, the vacuum holes need to be small enough. However, smaller vacuum hole dimension may lead to lower vacuum pressure. Therefore, there is a trade-off between the vacuum hole dimension and the vacuum pressure. The dimension (e.g. the length L) may be greater than 0.1 of the width W, such as 0.2 of the width W or 0.3 of the width W, but the present disclosure is not limited thereto. In the present embodiments, when the vacuum suction is functioning properly, the sufficient value of the vacuum pressure may be in a range approximately between 10 kbar and 150 kbar (10 kbar≤value≤150 kbar), such as 20 kbar, 50 kbar, 80 kbar, 100 kbar, or 125 kbar, but the present disclosure is not limited thereto. The sufficient value of the vacuum pressure may varied, depending on the vacuum hole dimension, the number of vacuum holes available, or other settings of the vacuum system.

When the vacuum pressure is not sufficient enough (e.g. less than the predetermine value), the vacuum suction of the light-emitting element 10 is not in effect, for example, the vacuum holes 310 are not covered by the light-emitting element 10. There are several factors that may result from the light-emitting element 10 not being properly suctioned. For example, the light-emitting element 10 to be attracted is still away from the vacuum holes 310. The light-emitting element 10 may not even reach the critical line 350. In an extreme case, during the transfer by the pusher 330, the light-emitting element 10 may be broken into segments. If the light-emitting element 10 were not intact, the vacuum suction may be compromised. Therefore, it is imperative to check whether the vacuum pressure reaches the sufficient value.

Under the circumstances when the vacuum pressure is not sufficient, the previous operations (such as the operations 1010, 1020, and 1030) need to be repeated. Before repeating the previous operations, the vacuum system should be turned off. The operation 1010 should be performed again to inspect the situation of the light-emitting element 10. For example, if the light-emitting element 10 is intact, then the method 1000 can proceed to the operation 1020 for another transferring attempt, followed by turning on the vacuum system in the operation 1030 to try to attract the light-emitting element 10 again. After that, the vacuum pressure should be checked again. If the vacuum pressure still does not reach the sufficient value, then the entire cycle of the operations 1010, 1020, and 1030 may need to be repeated the second time. Sometimes, it is common to repeat the cycle several times before the sufficient vacuum pressure is realized. Once the vacuum pressure reaches the sufficient value, the method 1000 may proceed into subsequent operations.

As shown in FIG. 5, in an operation 1050 of the method 1000, the transferring may be stopped when the light-emitting element 10 reaches the terminal position 10″.

As shown in FIG. 5, in an operation 1060 of the method 1000, another optical check is performed. The optical check may visually inspect the testing system 30 when the light-emitting element 10 is positioned at its terminal position 10″, as shown in FIGS. 3 and 4.

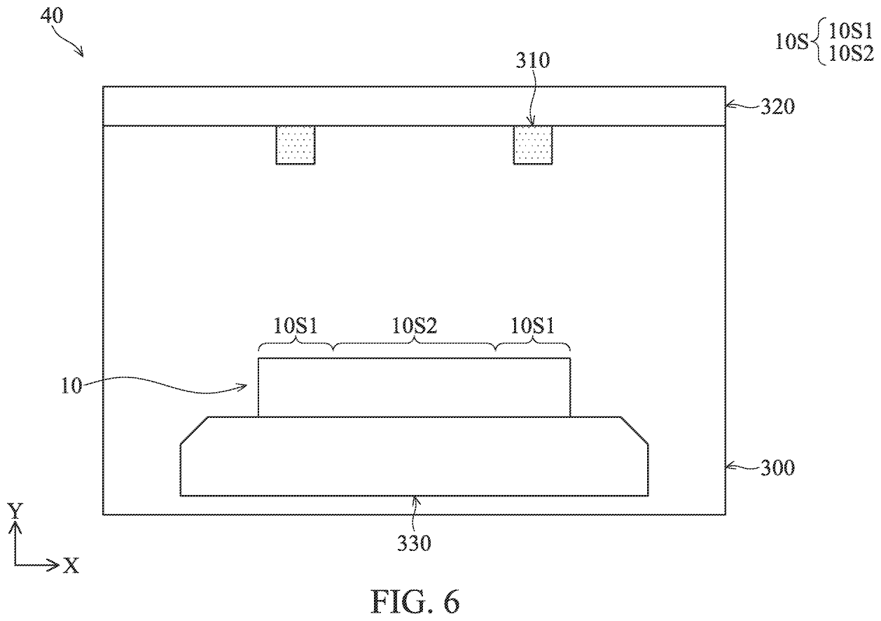

FIGS. 6, 7, and 8 are top views of testing systems 40, 50, and 60 with various designs, respectively, according to other embodiments of the present disclosure. As mentioned previously, the antireflection film is coated in such way that allows only a certain region on the output facet 10S for light to emit, resulting in a more concentrated light beam 200. For that reason, the output facet 10S may include one or more non-light emission regions 10S1 and a light emission region 10S2. According to some embodiments of the present disclosure, the arrangement of the vacuum holes 310 may correspond to the non-light emission regions 10S1 and the light emission region 10S2, but the present disclosure is not limited thereto. From the top view, the light emission region 10S2 may be located adjacent to the two non-light emission regions 10S1, for example, between the two non-light emission regions 10S1. For illustrative purpose, the intermediate position 10′, the terminal position 10″, and the critical line 350 are omitted. The features of the light-emitting element 10, the supporting stage 300, the vacuum holes 310, the stopper 320, and the pusher 330 are similar to those illustrated in FIG. 3, and the details are not described again herein to avoid repetition.

Referring to FIG. 6, in comparison with FIG. 3, only one vacuum hole 310 is disposed corresponding to each of the non-light emission regions 10S1 in the testing system 40. According to some embodiments of the present disclosure, the light-emitting element 10 may be transferred to a predetermined position (such as the critical line 350), and attracted toward the vacuum holes 310. In the present embodiment, the vacuum holes 310 are placed corresponding to the periphery of the light-emitting element 10. It should be understood that the phrase “A is disposed corresponding to B” used herein may indicate that A partially or wholly overlaps with B in the y-axis direction in the top view. As long as the vacuum holes 310 may attract the light-emitting element 10, limiting the number of vacuum holes 310 may reduce the manufacture cost of the testing system 40. Further, when the vacuum hole is disposed corresponding to each of the non-light emission regions 10S1, the occurrence of the light emission region 10S2 colliding with the stopper 320 will be decreased. Therefore, the reliability of the light-emitting element 10 may be improved.

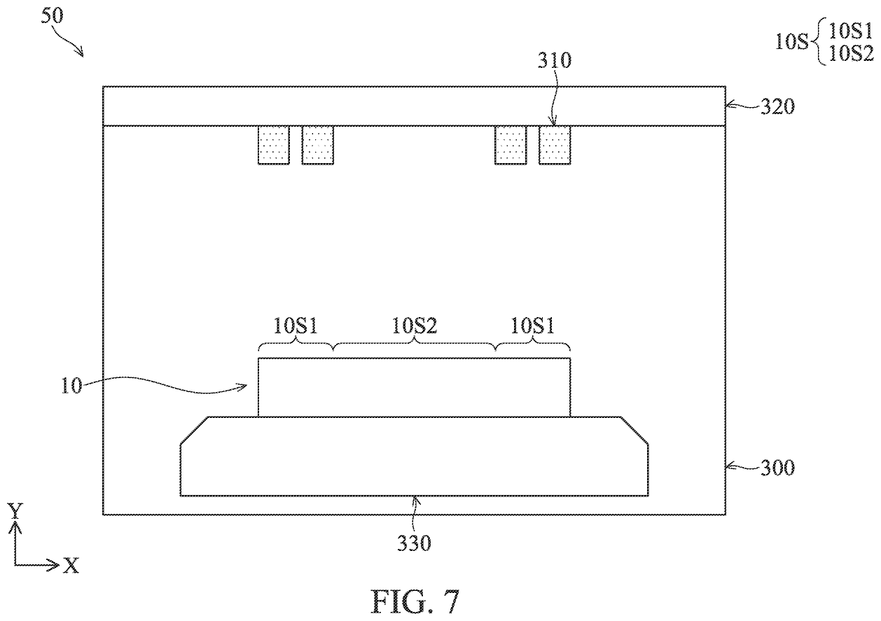

Referring to FIG. 7, in comparison with FIG. 6, two vacuum holes 310 are disposed corresponding to each of the non-light emission regions 10S1 in the testing system 50. According to some embodiments of the present disclosure, the light-emitting element 10 may be transferred to a predetermined position (such as reaching the critical line 350), and attracted toward the vacuum holes 310 by the stopper 320. In the present embodiment, more than one vacuum hole 310 may be placed corresponding to the periphery of the light-emitting element 10.

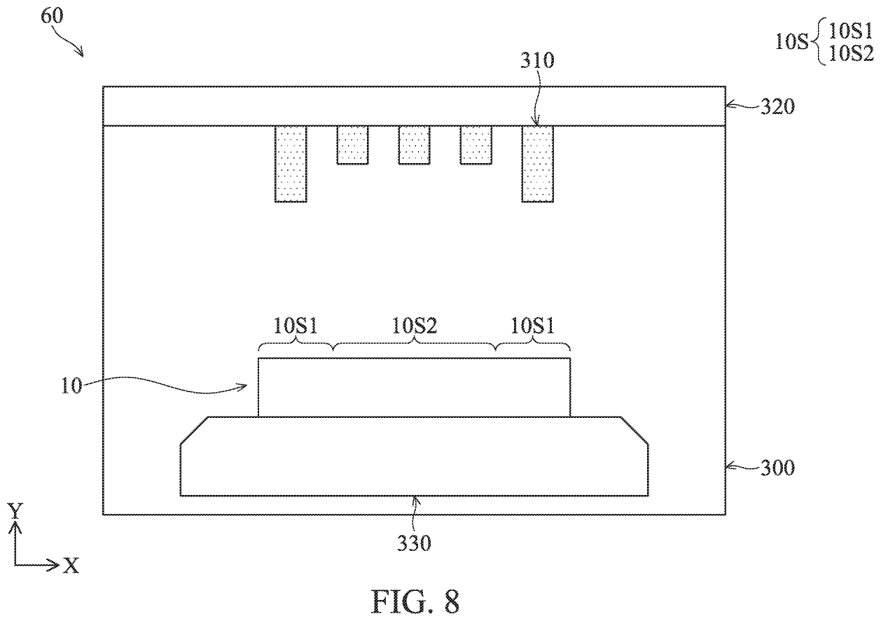

Referring to FIG. 8, in comparison with FIG. 3, the dimension of the vacuum holes 310 corresponding to the non-light emission regions 10S1 in the testing system 60 are greater than that of the vacuum holes 310 corresponding to the light emission region 10S, but the present disclosure is not limited thereto. The number and the dimension of the vacuum holes 310 are only for illustrative purpose, and the design may be modified according to the application needs.

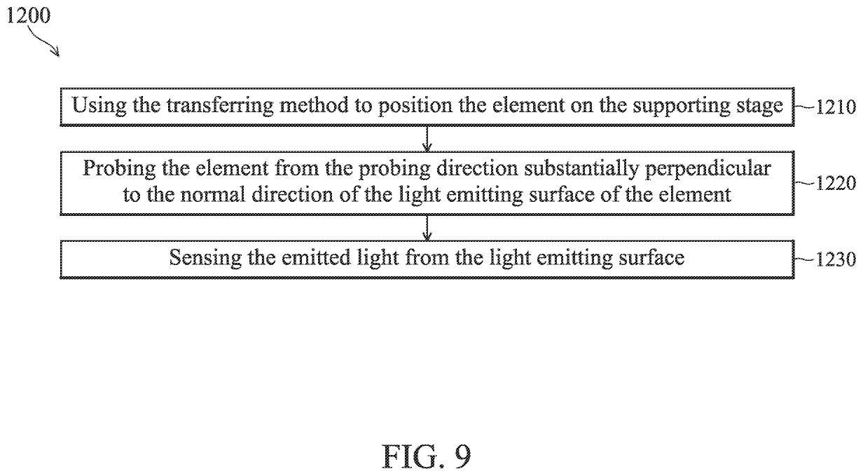

FIG. 9 is a flow diagram of an exemplary method 1200 for testing the light-emitting element 10, according to some embodiments of the present disclosure. The method 1200 combines the transferring method and the probing method for testing the light-emitting element 10. Incorporating both methods in operating the testing system may drastically reduce damage on the tested objects and enhance the optical sensing quality. It should be understood that the transferring method and the probing method do not depend from each other. Implementing either the transferring method or the probing method alone may significantly improve the testing quality.

As shown in FIG. 9, in an operation 1210 of the method 1200, the transferring method may be utilized to protect the light-emitting element 10 from damage. Reference can be made to FIGS. 3-8. According to some embodiments of the present disclosure, the light-emitting element 10 may be transferred to a predetermined position (such as reaching the critical line 350), and attracted toward the vacuum holes 310.

As shown in FIG. 9, in an operation 1220 of the method 1200, the probing method may be utilized to decrease the misalignment between the light-emitting element 10 and the optical sensor 400. Reference can be made to FIG. 2. According to some embodiments of the present disclosure, the probe may approach the light-emitting element 10 from an entry direction substantially perpendicular to the normal direction N of the output facet 10S.

As shown in FIG. 9, in an operation 1230 of the method 1200, the optical sensor 400 may receive the emitted light from the light-emitting element 10. Reference can be made to FIGS. 2-8. According to some embodiments of the present disclosure, the operation 1210 may reduce damage on the tested objects, while the operation 1220 may enhance the optical sensing quality. It should be understood that most of the present testing systems may be automatic. After inputting the proper settings, the operation 1230 may be carried out under superior testing quality with higher yield, and more accurate test results may be obtained.

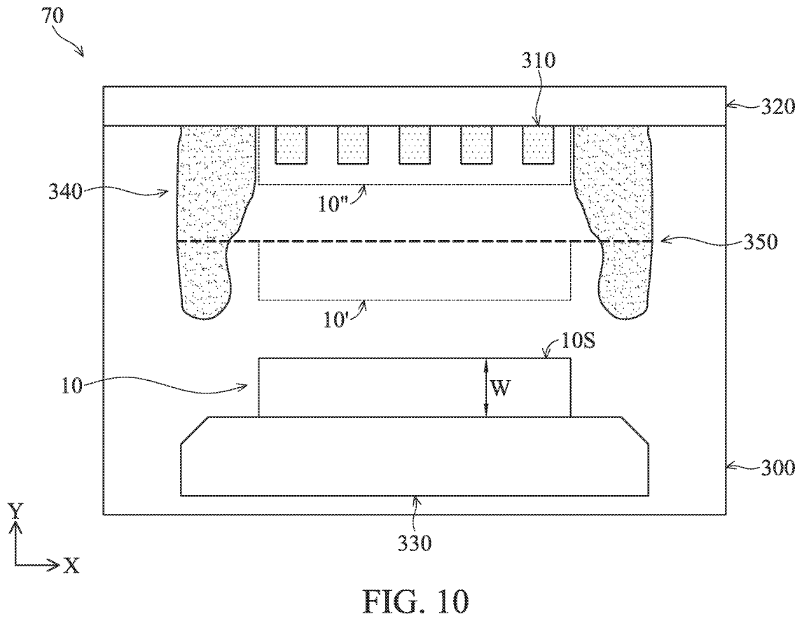

FIG. 10 is a top view of a testing system 70, according to yet other embodiments of the present disclosure. In comparison with FIG. 3, the testing system 70 may further include at least one blocking element 340 (also known as an alignment guide) disposed on the supporting stage 300. The features of the light-emitting element 10, the intermediate position 10′, the terminal position 10″, the supporting stage 300, the vacuum holes 310, the stopper 320, the pusher 330, and the critical line 350 are similar to those illustrated in FIG. 3, and the details are not described again herein to avoid repetition.

Referring to FIG. 10, the blocking element 340 may be disposed adjacent to the end of the terminal position 10″, but the present disclosure is not limited thereto. From the top view, the side of the blocking element 340 facing the vacuum holes 310 may be curved. The shapes of the blocking element 340 may be designed to have an increasing lateral dimension (e.g. in x-axis direction) toward the stopper 320. From the perspective of the output facet 10S of the light-emitting element 10S, the blocking element 340 may create a gradually merging path. When the light-emitting element 10 is attracted toward the vacuum holes 310, the light-emitting element 10 may be guided by the blocking element 340 into the desired position (such as the terminal position 10″).

The blocking element 340 may extend in the y-axis direction, and may function as an additional stopper to eliminate movement of the light-emitting element 10 in the x-axis direction. It should be noted that, unlike the stopper 320, the blocking element 340 may be not disposed in front of the output facet 10S. Therefore, it is not necessary for the blocking element 340 to maintain a relatively lower thickness. The thickness of the blocking element 340 may be greater than half the thickness of the light-emitting element 10. The addition of the blocking elements 340 is optional.

The present disclosure introduces the transferring method and the probing method to enhance the testing quality, to increase production yield, and to obtain more accurate test results. For the transferring method, the light-emitting element may be transferred to a predetermined position by a transferring component (e.g. the pusher), and attracted by the vacuum holes toward the stopper. In this way, the light-emitting element may be protected from potential damage. For the probing method, the probe may approach the light-emitting element from an entry direction substantially perpendicular to the normal direction of the output facet in a top view. In doing so, potential misalignment between the light-emitting element and the optical sensor may be decreased.

The foregoing outlines features of several embodiments so that those skilled in the art will better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined or re-organized in any suitable manner in one or more embodiments. One skilled in the prior art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A method of transferring a light-emitting element, comprising:
transferring the light-emitting element to a predetermined position by a transferring component, wherein the predetermined position is spaced apart a distance from at least one vacuum hole, and the distance is greater than half of a width of the light-emitting element; and
vacuuming the at least one vacuum hole to attract the light-emitting element.

2. The method as claimed in claim 1, further comprising sensing a pressure in the at least one vacuum hole and determining whether the pressure is greater than a predetermined value.

3. The method as claimed in claim 2, wherein the transferring component transfers the light-emitting element toward the at least one vacuum hole when the pressure is less than a predetermined value.

4. The method as claimed in claim 2, wherein the predetermined value is ranged from 10 kbar to 150 kbar.

5. The method as claimed in claim 1, further comprising sensing a light emitted from the light-emitting element.

6. The method as claimed in claim 1, wherein a length of the at least one vacuum hole is less than the width of the light-emitting element.

7. The method as claimed in claim 1, wherein the light-emitting element is an edge-emitting laser diode.

8. The method as claimed in claim 1, further comprising performing an optical inspection before transferring the light-emitting element.

9. A testing system for testing a light-emitting element having a light-emitting surface, comprising:
at least one probe for probing the light-emitting element in a probing direction perpendicular to a normal direction of the light-emitting surface in a top view.

10. The testing system as claimed in claim 9, wherein an included angle between the probing direction and a direction perpendicular to the normal direction is less than 5°.

11. The testing system as claimed in claim 9, wherein the light-emitting element is an edge-emitting laser diode.

12. The testing system as claimed in claim 9, further comprising a stopper attached to a supporting stage, wherein an extending direction in the top view of the stopper is substantially perpendicular to an extending direction in the top view of at least one blocking element disposed on the supporting stage.

13. The testing system as claimed in claim 12, wherein a thickness of a portion of the stopper protruding above the supporting stage is less than half of a thickness of the light-emitting element.

14. The testing system as claimed in claim 9, further comprising a supporting stage supporting the light-emitting element and the supporting stage comprising at least one vacuum hole.

15. The testing system as claimed in claim 14, wherein a length of the at least one vacuum hole is less than a width of the light-emitting element.

16. The testing system as claimed in claim 14, wherein the at least one vacuum hole is defined by the stopper and a recess in the supporting stage.

17. A method of testing a light-emitting element having a light-emitting surface, comprising:
positioning the light-emitting element on a supporting stage;
probing the light-emitting element with at least one probe, wherein a probing direction of the at least one probe is substantially perpendicular to a normal direction of the light-emitting surface in a top view; and
sensing a light emitted from the light-emitting surface.

18. The method as claimed in claim 17, wherein an included angle between the probing direction and a direction perpendicular to the normal direction is less than 5°.

19. The method as claimed in claim 17, wherein positioning the light-emitting element comprises vacuuming at least one vacuum hole to attract the light-emitting element.

20. The method as claimed in claim 17, wherein positioning the light-emitting element comprises performing an optical inspection.
